(19) United States
(12) Patent Application Publication
(10) Pub. No.: US 2025/0350673 A1
(43) Pub. Date: Nov. 13, 2025

(54) CASE

(71) Applicant: ASTERISK, INC., Osaka-shi, Osaka (JP)

(72) Inventors: Naoki KUMAMOTO, Osaka (JP); Kazuhiro KUBOTA, Osaka (JP)

(21) Appl. No.: 18/726,984

(22) PCT Filed: Jan. 10, 2023
(86) PCT No.: PCT/JP2023/000346

§ 371 Date: May 27, 2025

(30) Foreign Application Priority Data
Jan. 11, 2022 (JP) 2022-002582

(51) Int. Cl. H04M 1/02; G06F 1/16

(52) U.S. Cl. CPC H04M 1/0203; G06F 1/1628

(57) ABSTRACT

A case for a mobile information terminal having a front face with a screen, includes a top case to be disposed above the mobile information terminal, a bottom case to be disposed below the mobile information terminal, and a housing disposed between the top case and the bottom case and to house the mobile information terminal. The housing includes a first watertight part to be disposed at a periphery of the screen. The top case includes a frame to be superimposed on the first watertight part. The bottom case includes a locking part configured to lock the frame while biasing the frame against the periphery.

### CROSS REFERENCE TO RELATED APPLICATION

This Application is a US National Stage of PCT/JP2023/000346, filed Jan. 10, 2023, which claims priority to Japanese Patent Application No. 2022-002582 filed Jan. 11, 2022, the contents of each of which is herein incorporated by reference.

### BACKGROUND

### Technical Field

The present disclosure relates to cases that protect a mobile information terminal.

### Background Information

Mobile information terminals such as smartphones and tablet terminals are often housed in cases before use to cushion the terminal if dropped and to protect it from dust and moisture. For example, the case described in JP 2013-201739 A is a waterproof case that protects a mobile information terminal from moisture. This case has a housing section made of an elastic material and corresponding to the external shape of the mobile information terminal to be attached. This housing section has an opening that exposes the display of the mobile information terminal, and a peripheral section located at the periphery of the opening. The elastic material of the housing section has absorbency, whereby the case provides both good waterproof performance and good visibility of the display.

### SUMMARY

The waterproof case of JP 2013-201739 A, however, can have water seeping inside the absorbing section when the water absorption amount of the housing section becomes saturated. Therefore, it is difficult to completely prevent the entry of water. The present disclosure aims to provide a case that is capable of preventing moisture from entering the case.

To achieve the aim, a case according to one aspect of the present disclosure is for a mobile information terminal having a front face with a screen, and includes: a top case to be disposed above the mobile information terminal; a bottom case to be disposed below the mobile information terminal; and a housing that is disposed between the top case and the bottom case and houses the mobile information terminal. The housing includes a first watertight part to be disposed at a periphery of the screen, the top case includes a frame to be superimposed on the first watertight part, the bottom case includes a locking part that locks the frame while biasing the frame against the periphery.

The housing includes a second watertight part between the top case and the bottom case, the second watertight being sandwiched between and under pressure from the top case and the bottom case.

The housing includes a third watertight part having a shape along a chassis of the mobile information terminal.

The housing and the bottom case include a housing section that houses a peripheral device to be disposed along a back face of the mobile information terminal.

The case of the present disclosure prevents moisture from entering the case.

### BRIEF DESCRIPTION OF DRAWINGS

FIG. 1 is a plan view of a case according to a first embodiment of the present disclosure.

FIG. 2 is a side view of the case.

FIG. 3A is a plan view of a middle rubber that the case has, FIG. 3B is a back view of the middle rubber, FIG. 3C is a A-A cross-sectional view of the middle rubber, and FIG. 3D is a B-B cross-sectional view of the middle rubber.

FIG. 4A is a plan view of a bottom case that the case has, FIG. 4B is a back view of the bottom case, FIG. 4C is a C-C cross-sectional view of the bottom case, and FIG. 4D is a D-D cross-sectional view of the bottom case.

FIG. 5A is a plan view of a top case that the case has, FIG. 5B is a back view of the top case, FIG. 5C is a E-E cross-sectional view of the top case, and FIG. 5D is a F-F cross-sectional view of the top case.

FIG. 6A is a perspective view of a case according to a second embodiment of the present disclosure, and FIG. 6B is a perspective view of the case.

FIG. 7A is a photograph of a mobile information terminal and a peripheral device housed in the case according to the second embodiment, when viewed from the above, and FIG. 7B is a photograph of the mobile information terminal and peripheral device, when viewed from the below.

FIG. 8A is a plan view of a housing that the case has, and FIG. 8B is a back view of the housing.

FIG. 9A is a plan view of a bottom case that the case has, and FIG. 9B is a back view of the bottom case.

FIG. 10A is a plan view of a top case that the case has, and FIG. 10B is a plan view of the top case.

### DETAILED DESCRIPTION

### First Embodiment

Referring to the drawings, the following describes a case according to a first embodiment of the present disclosure.

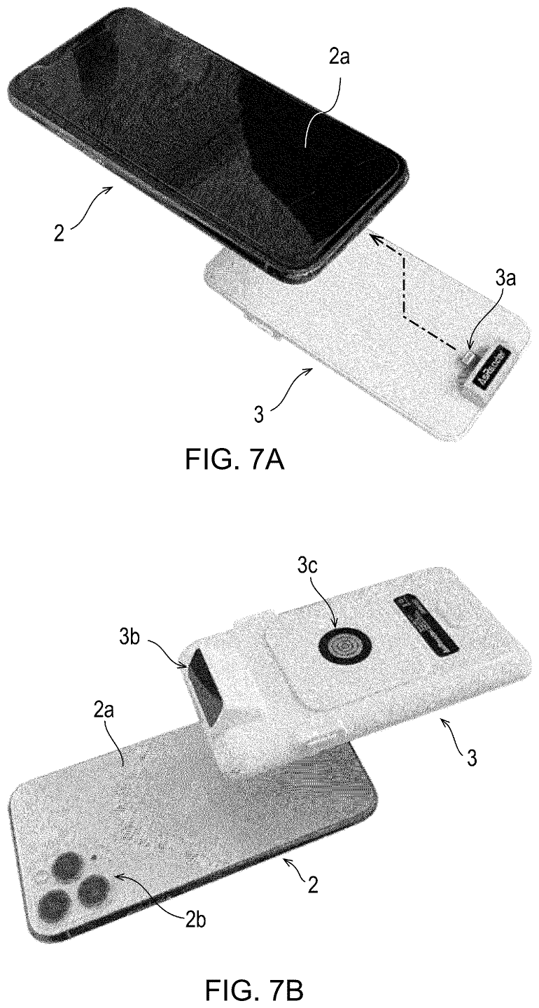

A case 1 according to the first embodiment is a case used for a mobile information terminal 2, including a known smartphone or tablet terminal. The mobile information terminal 2 of this embodiment has a plate-like shape that a user can hold in one hand. The mobile information terminal 2 has a front face, over the entire of which a touch panel display 2a (FIGS. 7A and 7B) is placed, and has a side face and a back face covered by a chassis 2b. The case 1 of the present embodiment protects the mobile information terminal 2 from impacts and also prevents water droplets from entering the mobile information terminal 2 through a joint between the touch panel display 2a and the housing.

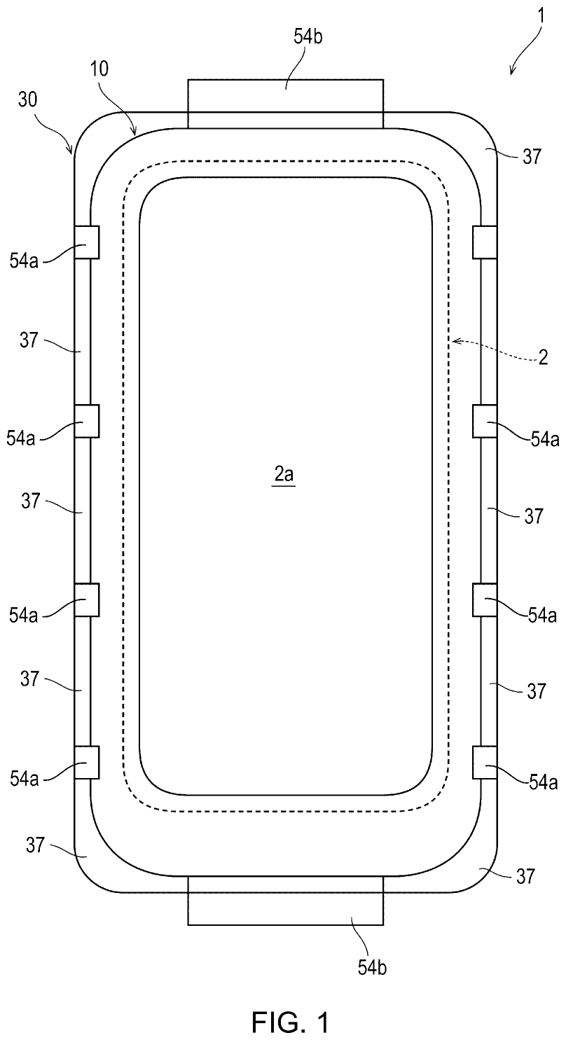

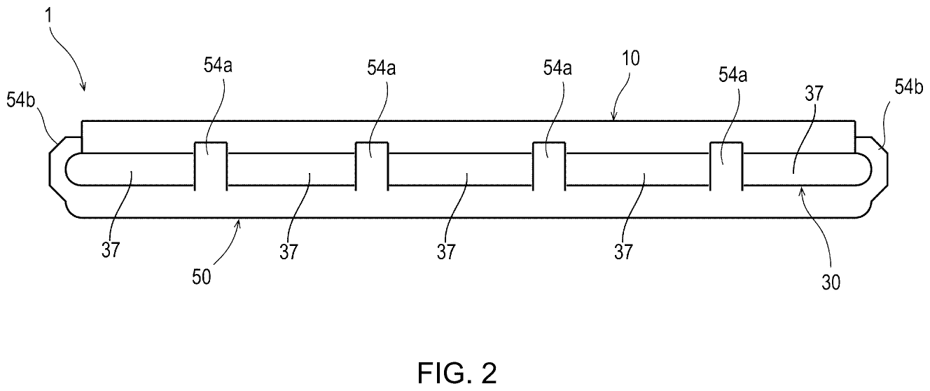

As shown in FIGS. 1 and 2, the case 1 of this embodiment includes a top case 10, a housing 30, and a bottom case 50. The housing 30 that holds the mobile information terminal 2 is placed between the top case 10 and the bottom case 50, whereby the case 1 houses the mobile information terminal 2 with the touch panel display 2a exposed.

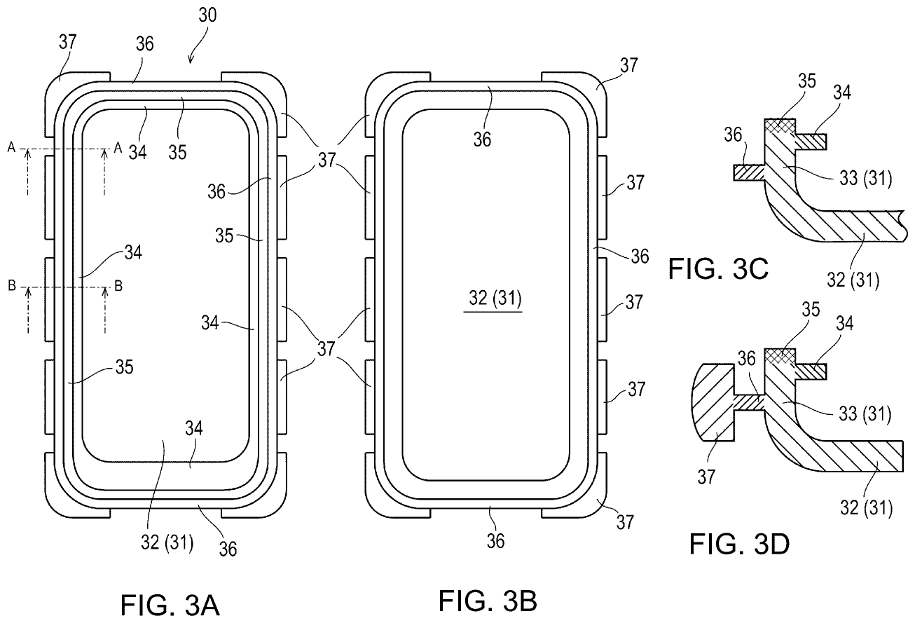

As shown in FIGS. 3A to 3D, the housing 30 is made of a soft material such as rubber, and has a housing section 31. The housing section 31 stores the mobile information terminal 2, and includes a bottom 32 and a wall 33. The bottom 32 is a part where the back face of the mobile information terminal 2 is placed, and has the same shape as the back face of the mobile information terminal 2. The wall 33 extends from the periphery of the bottom 32. The wall 33 encloses the side face of the mobile information terminal 2 and extends from the bottom 32 with the same length as the thickness of the mobile information terminal 2. That is, the housing section 31 is shaped so as to extend along the shape of the chassis of the mobile information terminal 2.

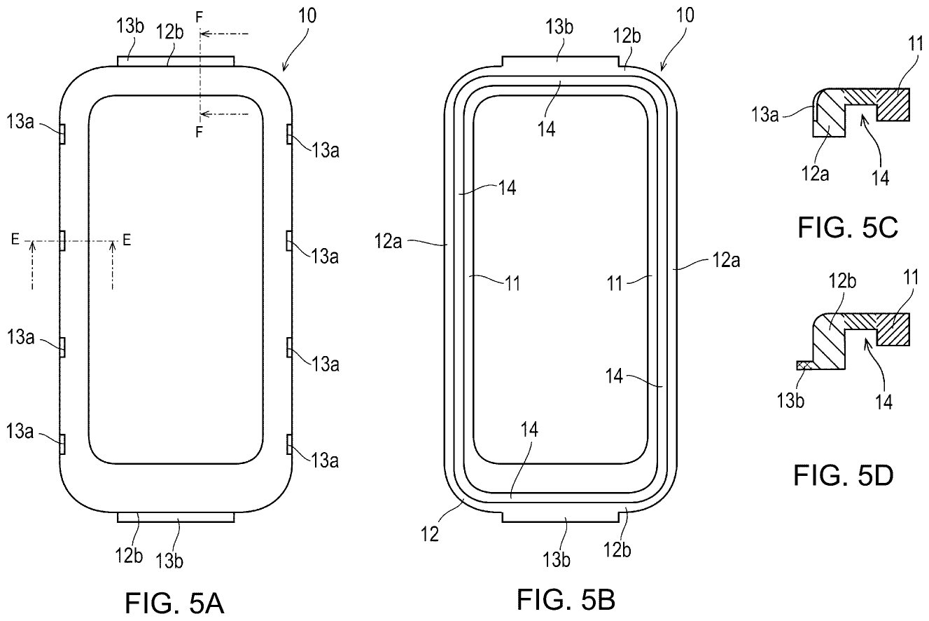

The housing 30 has a first watertight part 34 and a fitting part 35 at the end of the housing section 31 (the upper end of the wall 33). The first watertight part 34 stops water droplets from entering the housing section 31 from around the touch panel display 2a, and is placed above the periphery of the touch panel display 2a of the mobile information terminal 2 housed in the housing section 31. This first watertight part 34 extends flatwise inward from the end of the wall 33, and has a square shape in plan view. In this embodiment, the first watertight part 34 has a narrow frame shape with a width of about 2 mm to 3 mm. The fitting part 35 is fitted into a recess of the top case 10 described below, and extends upward (in the thickness direction of the mobile information terminal 2) from the edge of the wall 33 to have a square shape in plan view. Fitting of the fitting part 35 into the recess 14 (FIGS. 5A to 5D) of the top case 10 allows the first watertight part 34 to be positioned relative to the mobile information terminal 2.

The housing 30 also has a second watertight part 36 and a buffer part 37. The second watertight part 36 stops water droplets from entering the case 1 through a joint between the top case 10 and the bottom case 50, which will be described later. This second watertight part 36 extends outward from the wall 33, and has a square shape in plan view to surround the wall 33. The buffer part 37 is at the tip of the second watertight part 36 and bulges outward.

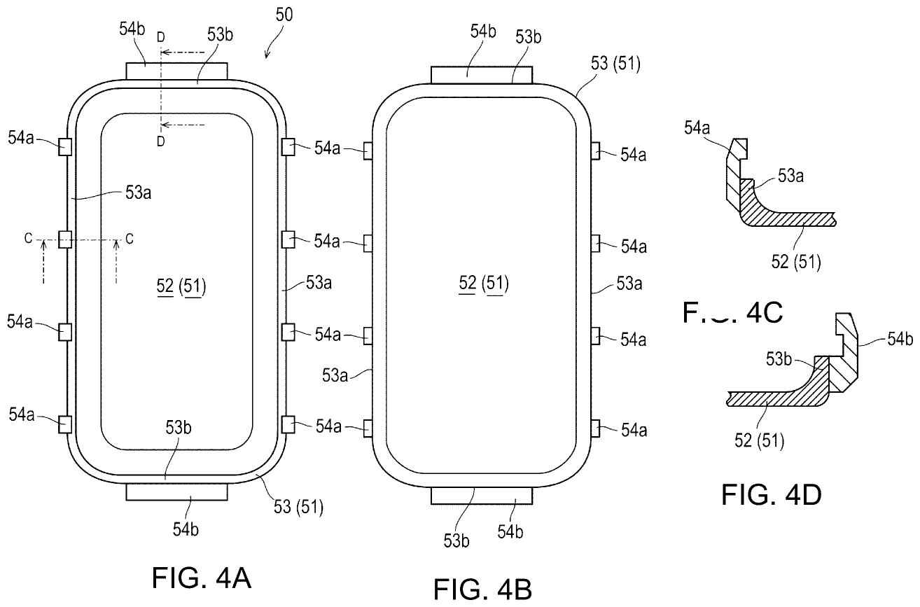

As shown in FIG. 2, the bottom case 50 is placed below the housing 30. As shown in FIGS. 1 and 4, the bottom case 50 includes a housing section 51. The housing section 51 stores the housing section 31 of the housing 30, and is superimposed on the back face of the housing section 31 of the housing 30. The housing section 51 of the bottom case 50 includes a bottom 52 and a wall 53. The bottom 52 is superimposed on the bottom 32 of the housing 30 and has the same shape as the bottom 32 of the housing 30. The wall 53 extends from the periphery of the bottom 52 of the bottom case 50. The wall 53 encloses the wall 33 of the housing 30 that the bottom case 50 houses, and extends to the same height as the wall 33 of the housing 30. The wall 53 of the bottom case 50 includes: a pair of long parts 53a extending in the longitudinal direction of the mobile information terminal 2; and a pair of short parts 53b extending in the transverse direction of the mobile information terminal 2. The pair of long parts 53a has a plurality of locking claws 54a, which serve as locking parts, on the outer face. These locking claws 54a lock with locked parts on the top case 10, and extend upward from the long parts 53a toward the top case 10. The pair of short parts 53b has locking claws 54b, which serve as locking parts, on the outer face. These locking claws 54b lock with locked parts on the top case 10, and extend upward from the short parts 53b toward the top case 10.

As shown in FIG. 2, the top case 10 is placed above the housing 30. As shown in FIGS. 1 and 5A to 5D, the top case 10 has a square frame shape, and has an inner frame 11 projecting downward (toward the housing 30). This inner frame 11 defines a narrow frame having a square shape when viewed from the back. The inner frame 11 has a width approximately equal to that of the first watertight part 34 of the housing 30, and is placed above the first watertight part 34.

The top case 10 has an outer frame 12 that extends downward along the outer face of the wall 33 of the housing 30 and is formed to abut against the upper face of the second watertight part 36 of the housing 30. This outer frame 12 includes: a pair of long parts 12a extending in the longitudinal direction of the mobile information terminal 2; and a pair of short parts 12b extending in the transverse direction of the mobile information terminal 2. The pair of long parts 12a has a plurality of recesses 13a, which serve as locked parts, on the outer face. These recesses 13a are formed to be caught by the locking claws 54a on the bottom case 50. The pair of short parts 12b has protrusions 13b, which serve as locked parts, on the outer face. These protrusions 13b protrude to be caught by the locking claws 54b on the bottom case 50. As described above, the inner frame 11 and outer frame 12 protrude/extend downward, which forms a recess 14 between the inner frame 11 and the outer frame 12.

As described above, the case of the present embodiment includes the top case 10, the housing 30, and the bottom case 50. The housing 30 is attached to the bottom case 50, and then the mobile information terminal 2 is housed in the housing 30. In this way, the housing 30 is attached to the bottom case 50 so that the housing section 31 of the housing 30 is housed in the housing section 51 of the bottom case 50 and the upper end of the housing section 51 of the bottom case 50 abuts against the lower face of the second watertight part 36 of the housing 30. Then, each of the buffer parts 37 of the housing 30 fits between corresponding locking claws 54a and 54b of the bottom case 50.

When the mobile information terminal 2 is housed in the housing section 31 of the housing 30, the first watertight part 34 is placed on the periphery of the touch panel display 2a of the mobile information terminal 2. In this way, the mobile information terminal 2 is housed in the housing 30, and then the top case 10 is attached. During the attachment, the top case 10 is press-fitted such that its outer frame fits into the second watertight part 36 of the housing 30. This locks the locked parts of the top case 10 to the locking parts of the bottom case 50.

After the top case 10 is attached, the inner frame of the top case 10 is held in a biased state against the periphery of the touch panel display 2a of the mobile information terminal 2 via the first watertight part 34 of the housing 30. This makes the first watertight part 34 come into close contact with the periphery of the touch panel display 2a and thus prevents water droplets from entering through the periphery of the touch panel display 2a. The second watertight part 36 of the housing 30 is sandwiched between and under pressure from the outer frame of the top case 10 and the end of the housing section of the bottom case 50. This reduces the entry of water droplets into the case through the joint between the top case 10 and bottom case 50.

### Second Embodiment

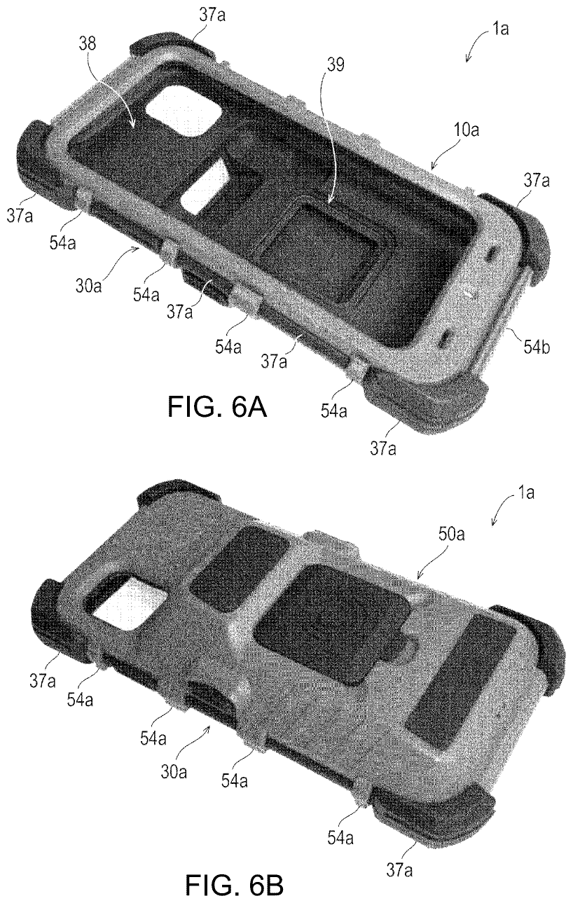

As shown in FIGS. 6A and 6B, a case 1a according to the second embodiment of the present disclosure is similar to the first embodiment in that it includes a top case 10a, a housing 30a, and a bottom case 50a, but differs from the first embodiment in that it protects a peripheral device 3 (FIGS. 7A and 7B) together with a mobile information terminal 2. The following descriptions on the case 1a of the present embodiment omit the configuration common to the first embodiment as appropriate, and give the details of the configuration different from the first embodiment.

The peripheral device 3 communicatively connects to the mobile information terminal 2 and cooperates with the mobile information terminal 2, and provides the mobile information terminal 2 with a new hardware function. The peripheral device 3 of this embodiment shown in FIGS. 7A and 7B is a reader that reads information from a symbol such as a barcode on an object to be read, such as an article (commodity). The reader is placed on the back face of the mobile information terminal 2 and connects by wire to the mobile information terminal 2 via a connector 3a so as to be communicable with the mobile information terminal 2. The peripheral device 3 includes: a light source that irradiates the symbol with reading light; a light receiving sensor that receives the light reflected from the symbol; and a microcomputer that obtains symbol information on the basis of the output of the light receiving sensor. This embodiment includes the light receiving sensor that is an image sensor, and the microcomputer analyzes an image generated by the image sensor to obtain information. The light source emits reading light and the light receiving sensor receives the light through a window 3b at the front end of the peripheral device 3. The peripheral device 3 has a concentrically shaped pattern electrode 3c exposed on the back face, and the pattern electrode 3c connects to a power terminal at the connector 3a. In this embodiment, the peripheral device 3 connects to the mobile information terminal 2 via the connector 3a, so that the microcomputer of the peripheral device 3 is communicatively connected to the CPU of the mobile information terminal 2. In another embodiment, the peripheral device 3 can also be communicable with the CPU of the mobile information terminal 2 via wireless communication such as Bluetooth.

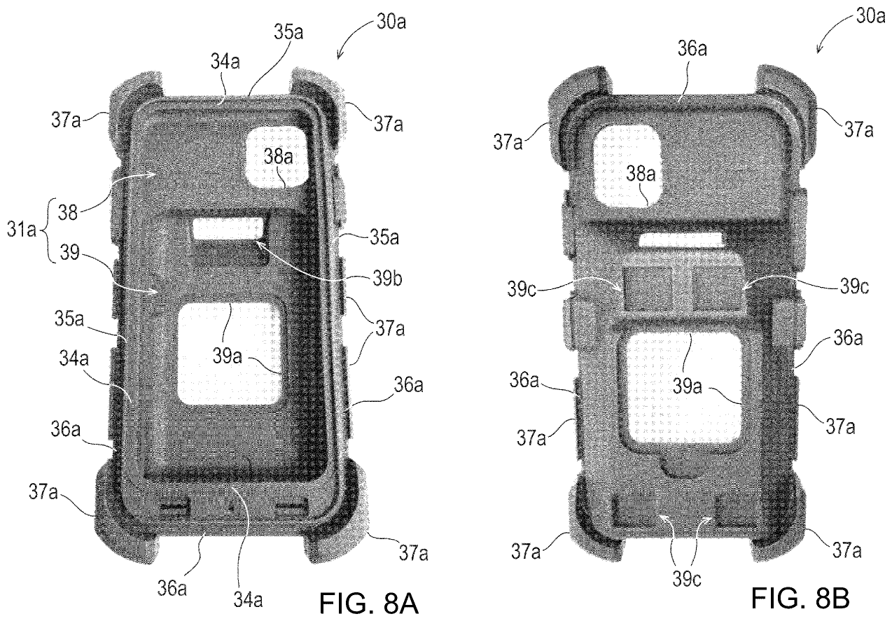

As shown in FIGS. 6A and 6B, the case 1a of this embodiment is assembled while placing the housing 30a between the top case 10a and the bottom case 50a. The housing 30a in this embodiment stores the mobile information terminal 2 and peripheral devices 3. As shown in FIGS. 8A and 8B, the housing 30a includes: a first watertight part 34a configured similarly to the first watertight part 34 of the first embodiment; a fitting part 35a configured similarly to the fitting part 35 of the first embodiment; a second watertight part 36a configured similarly to the second watertight part 36 of the first embodiment; and a buffer part 37a configured similarly to the buffer part 37 of the first embodiment.

In this embodiment, the housing section 31a of the housing 30a includes a terminal housing section 38 and a device housing section 39. The terminal housing section 38 houses the mobile information terminal 2 as in the first embodiment. The terminal housing section 38 has a rectangular opening 38a. This opening 38a is to expose a rear camera 2b of the mobile information terminal 2. The device housing section 39 houses the peripheral device 3 and has a recessed-shape along the external shape of the peripheral device 3. This device housing section 39 has openings 39a and 39b at positions corresponding to the window 3b and the pattern electrode 3c of the peripheral device 3. The device housing section 39 has a plurality of (four in this embodiment) rectangular recesses 39c on the back face. These rectangular recesses 39c each receive a magnet 55 on the bottom case 50a to be fitted therein. The mobile information terminal 2 is housed in the housing section 31a of this housing 30a with the peripheral device 3 connected via the connector.

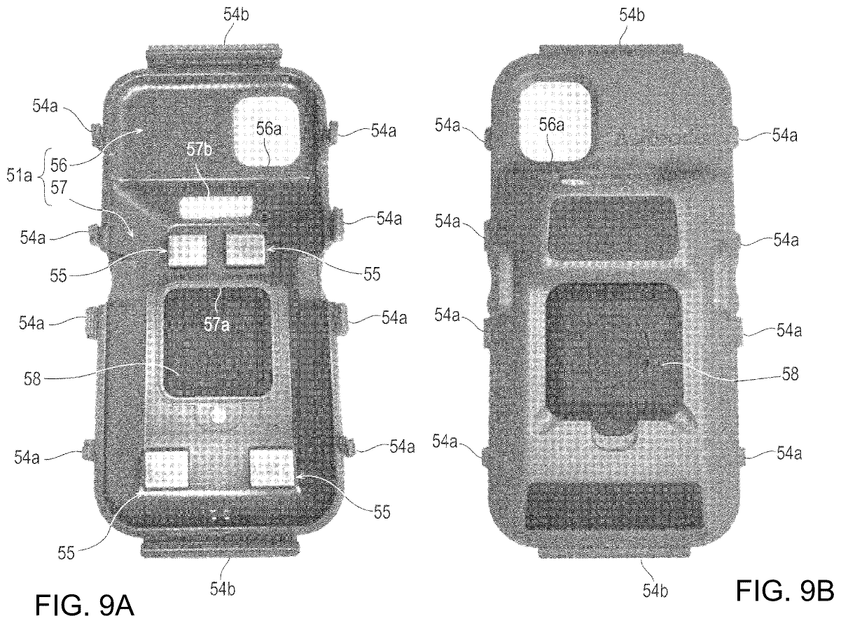

As shown in FIGS. 9A and 9B, the bottom case 50a of this embodiment includes locking claws 54a and 54b as in the first embodiment. The housing section 51a of the bottom case 50a in this embodiment is a recess along the shape of the housing section 31a of the housing 30a as described above. Specifically, the part of the housing 30a to place the terminal housing section 38 is shallowly recessed to correspond to the shape of the terminal housing section 38 (shallow recess 56), and the part of the housing 30a to place the device housing section 39 is deeply recessed to correspond to the shape of the device housing section 39 (deep recess 57). The shallow recess 56 has an opening 56a at a position corresponding to the opening 38a of the terminal housing section 38. This exposes the rear camera 2b of the mobile information terminal 2 through the opening 38a of the housing 30a and the opening 56a of the bottom case 50a. The deep recess 57 has openings at positions corresponding to the openings 39a and 39b of the device housing section 39. Specifically, openings 57a and 57b are at positions corresponding to the window 3b of the peripheral device 3, and the opening 57b is covered with a transparent plate. This lets the reading light output from the window 3b of the peripheral device 3 pass through the opening 39b of the housing 30a and the transparent plate to be applied to the object to be read. The reflected light from the object to be read then passes through the transparent plate and the opening 39b of the housing 30a and enters the reading sensor. The deep recess 57 has the opening 57a at a position corresponding to the pattern electrode 3c of the peripheral device 3, and this opening 57a has a removable rubber lid 58. When this lid 58 is removed, the pattern electrode 3c of the peripheral device 3 is exposed through the housing 30a and the opening 57a of the bottom case 50a. The deep recess 57 also has four magnets 55 that are placed around the opening 57a. These magnets 55 inside the bottom case 50a allow the case 1a, which houses the mobile information terminal 2 and peripheral device 3, to be attached to a metal wall or metal chassis, for example, and the user is able to operate the touch panel display 2a of the mobile information terminal 2 that is attached thereto.

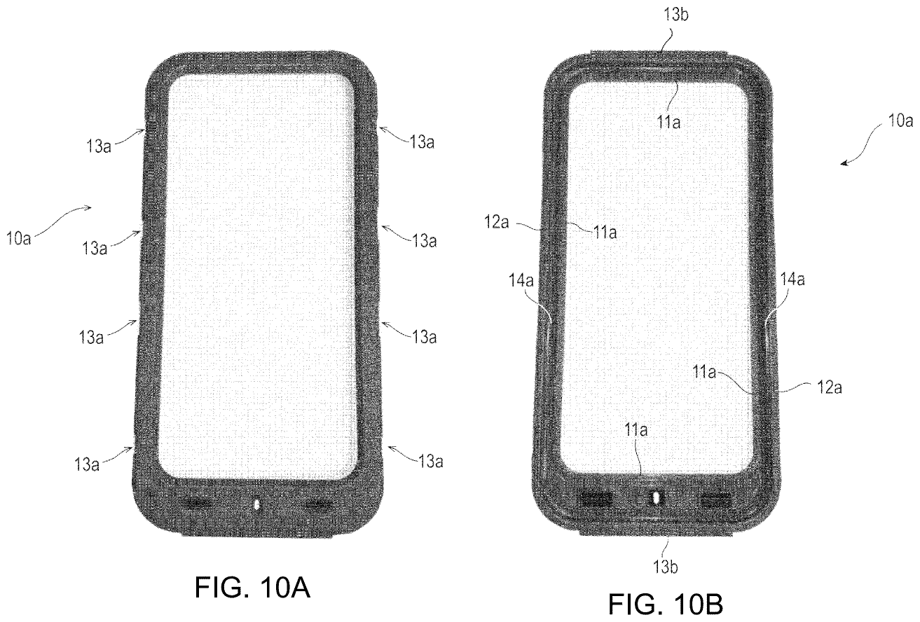

As shown in FIGS. 10A and 10B, the top case 10a of this embodiment has a square frame shape as in the first embodiment, and includes an inner frame 11a and an outer frame 12a that are configured similar to the inner frame 11 and the outer frame 12 of the first embodiment. The top case 10a also has a recess 14a similar to the recess 14 of the first embodiment, between the inner frame 11a and the outer frame 12a. The outer frame 12a also has recesses 13a and protrusions 13b, which are locked parts, similar to the first embodiment.

Similar to the first embodiment, the case of this embodiment is configured so that the mobile information terminal 2 is housed in the housing 30a with the housing 30a attached to the bottom case 50a. The top case 10a is then attached to the housing 30a and bottom case 50a.

1. A case for a mobile information terminal having a front face with a screen, comprising:
a top case to be disposed above the mobile information terminal;
a bottom case to be disposed below the mobile information terminal; and
a housing disposed between the top case and the bottom case and configured to house the mobile information terminal,
the housing including a first watertight part to be disposed at a periphery of the screen,
the top case includes a frame to be superimposed on the first watertight part, and
the bottom case includes a locking part configured to lock the frame while biasing the frame against the periphery.

2. The case according to claim 1, wherein the housing includes a second watertight part between the top case and the bottom case, the second watertight part being sandwiched between and configured to be under pressure from the top case and the bottom case.

3. The case according to claim 1, wherein the housing includes a third watertight part configured to have a shape along a chassis of the mobile information terminal.

4. The case according to claim 1, wherein the housing and the bottom case include a housing section configured to house a peripheral device to be disposed along a back face of the mobile information terminal.

5. The case according to claim 2, wherein the housing includes a third watertight part configured to have a shape along a chassis of the mobile information terminal.

6. The case according to claim 2, wherein the housing and the bottom case include a housing section configured to house a peripheral device to be disposed along a back face of the mobile information terminal.

7. The case according to claim 3, wherein the housing and the bottom case include a housing section configured to house a peripheral device to be disposed along a back face of the mobile information terminal.
